(19) United States
(12) Patent Application Publication
(10) Pub. No.: US 2026/0342359 A1
(43) Pub. Date: Oct. 29, 2026

(54) METHODS, SYSTEMS, AND APPARATUS FOR DETERMINATION OF MOTHER CODE LENGTH

(71) Applicant: Huawei Technologies Co., Ltd., Shenzhen (CN)

(72) Inventors: Huazi Zhang, Hangzhou (CN); Wen Tong, Ottawa (CA); Jianglei Ma, Ottawa (CA)

(21) Appl. No.: 19/675,113

(22) Filed: May 12, 2026

Related U.S. Application Data
(63) Continuation of application No. PCT/CN2024/080361, filed on Mar. 6, 2024.
(60) Provisional application No. 63/598,609, filed on Nov. 14, 2023.

(51) Int. Cl. H03M 13/05; G06F 40/20

(52) U.S. Cl. CPC H03M 13/05; G06F 40/20

(57) ABSTRACT

Embodiments of this disclosure provide methods and an apparatus for determination of mother code length for polar codes. In an example method, a plurality of mother code lengths are determined, and a plurality of information bits are encoded based on the plurality of mother code lengths. The plurality of information bits are encoded to a plurality of code words. The plurality of code words correspond to the plurality of mother code lengths.

### CROSS-REFERENCE TO RELATED APPLICATIONS

This application is a continuation of International Application No. PCT/CN2024/080361, filed on Mar. 6, 2024, which claims priority to and the benefit of U.S. provisional patent application Ser. No. 63/598,609, entitled “Determination of Mother Code Length for Polar Codes,” filed on Nov. 14, 2023. The disclosures of the aforementioned applications are hereby incorporated by reference in their entireties.

### TECHNICAL FIELD

The present application relates to coding, and in particular to methods, systems, and apparatus for determination of mother code length.

### BACKGROUND

In the field of communication systems, channel coding is usually used to improve the reliability of signal transmission and ensure communication quality. The existing code methods have been proven to achieve the theoretical channel capacity, which have relatively simple encoding and decoding complexity.

With the rapid evolution of wireless communication systems, some new wireless communication systems, such as so-called sixth-generation (6G) systems will aim to support multiple scenarios, including immersive communication, massive communication, hyper reliable and low-latency communication, and so on.

However, the existing code schemes are not flexible to support these scenarios that need at least one retransmission or a plurality of codes of multiple redundancy versions due to the design principles of mother code.

### SUMMARY

The following examples pertain to embodiments described throughout this disclosure.

One or more embodiments are related to a method. The method comprising: determining a plurality of mother code lengths; encoding a plurality of information bits based on the plurality of mother code lengths to obtain a plurality of code words, the plurality of code words correspond to the plurality of mother code lengths.

In some embodiments, after the plurality of mother code lengths is determined, codes for different transmission times or redundancy versions could be obtained during the encoding process. Therefore the communication systems may be able to support multiple scenarios, which is very useful and convenient in transmission process.

In some implements of the method, determining a plurality of mother code lengths comprising: determining a plurality of mother code lengths based on a set of parameters, the set of parameters comprising one or more of the following: a minimum code rate, a maximum code rate, a minimum mother code length, a maximum mother code length, a rate matching output length, an index of redundancy version, a transmission index, a number of transmission times, and a self-decodable indicator.

In some embodiments, the number of the plurality of mother code lengths and the value of each of the plurality of mother code lengths may be determined by the set of parameters. Different number of the plurality of mother code lengths and different value of each of the plurality of mother code lengths may support different scenario that required different number of retransmissions or different index of redundancy versions.

In some implements of the method, each of the plurality of mother code lengths is based on the mother code length parameter and a first coefficient.

In some embodiments, the mother code length parameter refers to the current calculated mother code length, the first coefficient refers to the fixed number of extension times. Therefore with different value of the first coefficient and the mother code length parameter, different mother code length may be determined. In the embodiments of the disclosure, no specific limitation is imposed on the value of the first coefficient.

For example, in the case of “optional retransmission”, which means that retransmissions may not occur, in some embodiments the mother code length parameter refers to an initial mother code length for the initial transmission. And the mother code length parameter may be determined first. Then mother code lengths for retransmissions may be determined based on the mother code length parameter and different values of the first coefficient.

For example, in the case of “forced retransmission”, which means that at least one retransmission will definitely occur, in some embodiments the mother code length parameter refers to a mother code length for retransmission. And the mother code length parameter may be determined first. Then the initial mother code length and other mother code lengths for retransmissions may be determined based on the mother code length parameter and different values of the first coefficient.

For example, in the case of “pre-allocation of transmission resources”, in some embodiments the mother code length parameter refers to a reference mother code length. And the mother code length parameter may be determined first. Mother code lengths for transmissions (including the initial transmission and retransmissions), or redundancy versions may be based on the mother code length parameter and different values of the first coefficient.

In some implements of the method, a method for obtaining the mother code length parameter comprises: obtaining a rate matching output length, a number of the plurality of information bits, a minimum code rate, and a minimum mother code length; obtaining a first stage mother code length based on the rate matching output length; obtaining a second stage mother code length based on the number of the plurality of information bits and the minimum code rate; obtaining a third stage mother code length; obtaining the mother code length parameter based on the first stage mother code length, the second stage mother code length, the third stage mother code length, and the minimum mother code length.

In some embodiments, different mother code lengths may be obtained based on the mother code length parameter. In some embodiments, the first stage mother code length, the second stage mother code length and the third stage mother code length may be different with different rate matching output length, different number of the plurality of information bits, different minimum code rate, and different minimum mother code length. The method of obtained the first stage mother code length, the second stage mother code length and the third stage mother code length are very flexible, and is related to the scene that supported by the community system.

In some implements of the method, the first stage mother code length is the smallest power-of-2 integer which is larger than the rate matching output length.

In some implements of the method, the first stage mother code length is equal to 2^{┌log}^{₂} ^{E┐}, E is the rate matching output length.

In some embodiments, the first stage mother code length may be the difference between the smallest power-of-2 integer which is larger than the rate matching output length and a first integer. The integer may be 1, −1, or others. In the embodiments of the disclosure, no specific limitation is imposed on the first integer.

In some implements of the method, the first stage mother code length is the largest power-of-2 integer which is smaller than the rate matching output length.

In some implements of the method, the first stage mother code length is equal to 2^{└ log}^{₂}^{E┘}, E is the rate matching output length.

In some embodiments, the first stage mother code length may be the difference between the largest power-of-2 integer which is smaller than the rate matching output length and a second integer. The second integer may be 1, −1, or others. In the embodiments of the disclosure, no specific limitation is imposed on the integer.

In some implements of the method, the mother code length parameter is related to one or more of the followings: a number of transmission times, a type of channel, an index of redundancy version, and a communication scenario.

In some embodiments, different number of transmission times, different type of channel, different index of redundancy version, and different communication scenario may results in different mother code length parameter. Therefore a plurality of mother code lengths may be determined by different mother code length parameter.

In some implements of the method, the second stage mother code length is the smallest power-of-2 integer which leads to the second mother code rate is smaller than the minimum code rate, the second mother code rate is the quotient of the number of the plurality of information bits and the second stage mother code length.

In some implements of the method, the second stage mother code length is equal to 2^{┌log}^{₂}^{(K/R}^{ₘᵢₙ}^{)┐}, K is the number of the plurality of information bits and Rmin is the minimum code rate.

In some implements of the method, the second stage mother code length is the largest power-of-2 integer which leads to the second mother code rate is larger than the minimum code rate, the second mother code rate is the quotient of the number of the plurality of information bits and the second stage mother code length.

In some implements of the method, the second stage mother code length is equal to 2^{└ log}^{₂}^{(K/R}^{ₘᵢₙ}^{)┘}, and K is the number of the plurality of information bits and Rmin is the minimum code rate.

In some embodiments, the second stage mother code length may be different due to different method, which is helpful for the community system used to support multiple scenarios.

In some implements of the method, the minimum code rate is related to one or more of the followings: a number of transmission times, a type of channel, a type of service, an index of redundancy version, and a communication scenario.

In some implements of the method, n the minimum code rate is the same as a first constant.

In some embodiments, the first constant may be any positive integer. In the embodiments of the disclosure, no specific limitation is imposed on the first constant.

In some implements of the method, the third stage mother code length is the same as a second constant.

In some embodiments, the second constant may be any positive integer. In the embodiments of the disclosure, no specific limitation is imposed on the second constant.

In some implements of the method, obtaining the third stage mother code length based on a maximum mother code length.

In some implements of the method, the maximum mother code length is related to one or more of the followings: a type of channel, a type of service, and device capability.

In some implements of the method, the maximum mother code length is a power-of-2 integer.

In some implements of the method, the maximum mother code length is the same as the length of a nested reliability sequence.

In some embodiments, the maximum mother code length may be different, which is helpful for the community system used to support multiple scenarios.

In some implements of the method, the maximum mother code length is the same as a third constant.

In some embodiments the third constant may be any positive integer. In the embodiments of the disclosure, no specific limitation is imposed on the third constant.

In some implements of the method, the minimum mother code length is the same as a fourth constant.

In some embodiments the fourth constant may be any positive integer. In the embodiments of the disclosure, no specific limitation is imposed on the fourth constant.

In some implements of the method, the minimum mother code length is related to a type of channel or service.

In some implements of the method, each of the plurality of mother code lengths is the same as the maximum mother code length.

In some implements of the method, the plurality of mother code lengths are equal to a plurality of constants.

In some embodiments, the plurality of constants may be any positive integers. In the embodiments of the disclosure, no specific limitation is imposed on the plurality of constants.

In some implements of the method, each of the plurality of mother code lengths is equal to the product of the mother code length parameter and a first coefficient.

In some implements of the method, the first coefficient is related to one or more of the followings: a number of transmission times, device capability, a type of channel, a type of service, a communication scenario, an index of redundancy version.

In some implements of the method, the first coefficient is a positive integer.

In some implements of the method, the first coefficient is equal to a quotient of two positive integers.

In some implements of the method, encoding a plurality of information bits based on the plurality of mother code lengths, comprising: determining one or more information bits sets based on the plurality of information bits and the plurality of mother code lengths.

In some embodiments, one or more information bits sets may be obtained based on the plurality of mother code lengths, which may be used for a plurality of transmissions or redundancy versions.

One or more embodiments are related to a method. The method comprising: obtaining a plurality of code words, the plurality of code words correspond to a plurality of mother code lengths; decoding the plurality of code words to obtain a plurality of sequences, the plurality of sequences correspond to the plurality of information bits.

In some embodiments, the plurality of code words may be converted to a plurality of first sequences by demodulation or other ways. The number of the plurality of first sequences is related to at least one of the followings: a number of redundancy versions, a number of transmission times, and a self-decodable indicator. Flexible decoding process may be executed according to the plurality of first sequences, and the communication systems may be able to support multiple scenarios with different transmission times or redundancy versions, which is very useful and convenient in transmission process. In the embodiments of the disclosure, no specific limitation is imposed on the ways of obtaining the plurality of first sequences, and the algorithm and technique in decoding. In some implements of the method, the plurality of mother code lengths are determined based on a set of parameters, the set of parameters comprising one or more of the following: a minimum code rate, a maximum code rate, a minimum mother code length, a maximum mother code length, a rate matching output length, an index of redundancy version, a transmission index, a number of transmission times, a self-decodable indicator.

In some implements of the method, each of the plurality of mother code lengths is related to a mother code length parameter and a first coefficient.

In some implements of the method, a method for obtaining the mother code length parameter comprises: obtaining a rate matching output length, a number of the plurality of information bits, a minimum code rate, and a minimum mother code length; obtaining a first stage mother code length based on the rate matching output length; obtaining a second stage mother code length based on the number of the plurality of information bits and the minimum code rate; obtaining a third stage mother code length; obtaining the mother code length parameter based on the first stage mother code length, the second stage mother code length, the third stage mother code length, and the minimum mother code length.

In some implements of the method, the first stage mother code length is the smallest power-of-2 integer which is larger than the rate matching output length.

In some implements of the method, the first stage mother code length is the largest power-of-2 integer which is smaller than the rate matching output length.

In some implements of the method, the mother code length parameter is related to one or more of the followings: a number of transmission times, a type of channel, an index of redundancy version, and a communication scenario.

In some implements of the method, the second stage mother code length is the smallest power-of-2 integer which leads to the second mother code rate is smaller than the minimum code rate, wherein the second mother code rate is the quotient of the number of the plurality of information bits and the second stage mother code length.

In some implements of the method, the second stage mother code length is the largest power-of-2 integer which leads to the second mother code rate is larger than the minimum code rate, wherein the second mother code rate is the quotient of the number of the plurality of information bits and the second stage mother code length.

In some implements of the method, the minimum code rate is related to one or more of the followings: a number of transmission times, a type of channel, a type of service, an index of redundancy version, and a communication scenario.

In some implements of the method, obtaining the third stage mother code length based on a maximum mother code length.

In some implements of the method, the maximum mother code length is related to one or more of the followings: a type of channel, a type of service, and device capability.

In some implements of the method, the maximum mother code length is a power-of-2 integer.

In some implements of the method, the maximum mother code length is the same as the length of a nested reliability sequence.

In some implements of the method, the minimum mother code length is related to a type of channel or service.

In some implements of the method, one of the plurality of mother code lengths is the same as the maximum mother code length.

In some implements of the method, each of the plurality of mother code lengths is related to the product of the mother code length parameter and the first coefficient.

In some implements of the method, the first coefficient is related to one or more of the followings: a number of transmission times, device capability, a type of channel, a type of service, a communication scenario, and an index of redundancy version.

In some implements of the method, the first coefficient is equal to a quotient of two positive integers.

One or more embodiments can include an apparatus, the apparatus comprises a function or unit configured to cause the apparatus to perform the method of the present disclosure.

One or more embodiments can include an apparatus, and the apparatus comprising a processor configured to cause the apparatus to perform the method of the present disclosure.

One or more embodiments can include an apparatus/chipset system, the apparatus/chipset system comprising: at least one processor executing instructions stored in a computer-readable medium to implement the method of the present disclosure.

One or more embodiments can include a computer program comprising instructions, the instructions, when executed by a processor, may cause the processor to implement the method of the present disclosure.

One or more embodiments can include a non-transitory computer-readable medium storing programming, the programming, when executed by a processor, may cause the processor to implement the method of the present disclosure.

The present disclosure encompasses these and other aspects or embodiments.

### BRIEF DESCRIPTION OF THE DRAWINGS

For a more complete understanding of the present embodiments, and the advantages thereof, reference is now made, by way of example, to the following descriptions taken in conjunction with the accompanying drawings.

FIG. 1 is a simplified schematic illustration of a communication system.

FIG. 2 is a block diagram illustration of the example communication system in FIG. 1.

FIG. 3 illustrates an example electronic device and examples of base stations.

FIG. 4 illustrates units or modules in a device.

FIG. 5 is a trellis graph illustrating an example of a polar code.

FIG. 6 is a table of sub-block interleaver pattern.

FIG. 7 is a diagram illustrating puncturing and shortening with a cyclic buffer.

FIG. 8 is a diagram illustration of an example of the encoding process for 4 transmissions.

FIG. 9 is a diagram illustration of an example of the encoding process of the initial transmission.

FIG. 10 is a diagram illustration of an example of the encoding process of the first retransmission.

FIG. 11 is a block diagram illustration of an example of a polar transform matrix of three transmissions.

FIG. 12 is a flow schematic illustration of an example of an encoding method.

FIG. 13 is a flow schematic illustration of an example of a decoding method.

FIG. 14 is a block diagram illustration of an example of determination of mother code lengths.

### DETAILED DESCRIPTION OF ILLUSTRATIVE EMBODIMENTS

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. In some embodiments these concepts and applications fall within the scope of the disclosure and the accompanying claims.

Reference may be made, above and/or elsewhere herein, to particular examples (such as “the method”) that have or provide certain features. It should be appreciated that these are example only, and such features need not necessarily be provided in all examples or embodiments, or may be provided in other examples or embodiments.

Although embodiments of methods of determination of mother code length in the present disclosure may illustrate by taking polar codes as examples, these methods may be applicable for other codes. For example, these methods of determination of mother code length in the present disclosure may be applicable for Low Density Parity Check (LDPC) codes, Turbo codes, Reed Muller (RM) codes, convolutional codes, product codes, etc. In the embodiments of the disclosure, no specific limitation is imposed on the type of codes.

In methods of determination of mother code length for polar codes, determination of a plurality of mother code lengths may reduce decoder complexity in high-throughput communications scenarios, and improve performance in cases with multiple transmissions, such as Incremental-Redundancy Hybrid automatic repeat request (IR-HARQ).

In methods of determination of mother code length for LDPC codes, determination of a plurality of mother code lengths may reduce buffer size for terminals with limited buffer size and lower device capability.

In methods of determination of mother code length for Turbo codes, different mother code length may be determined for different communication scenarios, such as Internet of Things (IoT) devices that requires shorter code length.

In methods of determination of mother code length for Convolutional codes, determination of a plurality of mother code lengths may provide flexible mother code lengths (in the form of constraint length), which may result in a good tradeoff between decoding complexity and performance.

In methods of determination of mother code length for RM codes, multiple mother code lengths are provided, especially including longer mother code length, which may further enhance the coding gain of very short codes (with short block length).

In methods of determination of mother code length for Product codes, different mother code length for the component codes in a product code may enable a flexible tradeoff between encoding/decoding parallelism and coding gain.

The background of methods of the determination of mother code length provided in the embodiments of the present disclosure is explained below.

In wireless communications, channel quality is constantly changing due to the fading effects at both fast and slow scale. Accordingly, channel coding has always been designed to adapt to the channel states. Modulation coding scheme (MCS) adaptation is a powerful method to combat varying channel states, in which the modulation order and code length and coding rate can be changed in real time. Therefore, it requires that a channel coding scheme can flexibly change the code length and code rate in a fine-grained way, and at the same time achieve good error correction performance in all possible configurations. This fine-grained flexibility of channel codes is one of the most challenging problems for engineers in this domain.

At the same time, the complexity of both encoding and decoding algorithms needs to be sufficiently low. In hardware, complexity can be evaluated through measuring chip area and energy efficiency. They are related to algorithmic complexity, but are more closely related to hardware cost and battery life. Therefore, there exists a desire to reduce implementation complexity when designing coding schemes.

Future communication systems, such as 6G systems, may aim to support several challenging scenarios, including for example immersive communication, massive communication, and hyper reliable and low-latency communication. The KPIs that are related to channel coding include coding gain, reliability, throughput, latency and their tradeoffs. For example, the throughput target of 6G may reach above 1 Tbps, and the energy efficiency target may decrease to 1 pJ/bit. Meanwhile, a coding scheme supporting flexible rate matching and IR-HARQ schemes is also beneficial. Accordingly, it is desirable yet challenging to design a code ensemble to fulfill all these KPIs and capabilities.

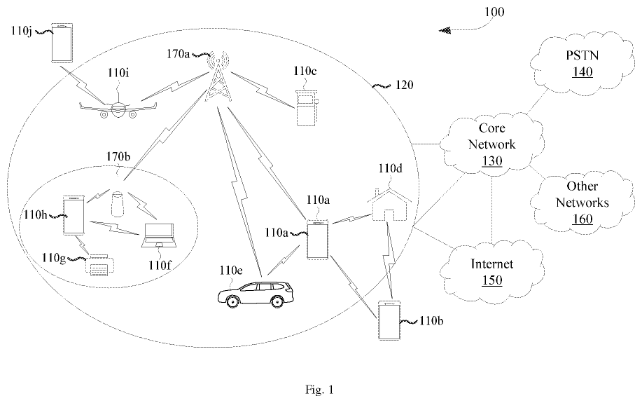

Referring to FIG. 1, as an illustrative example without limitation, a simplified schematic illustration of a communication system is provided. The communication system 100 comprises a radio access network 120. The radio access network 120 may be a next generation (e.g. sixth generation (6G) or later) radio access network, or a legacy (e.g. 5G, 4G, 3G or 2G) radio access network. 5G refers to 5th generation, 4G refers to 4th generation, 3G refers to 3th generation, 2G refers to 2th generation. Legacy wireless technology may also include 2nd generation (2G). One or more communication electronic devices (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

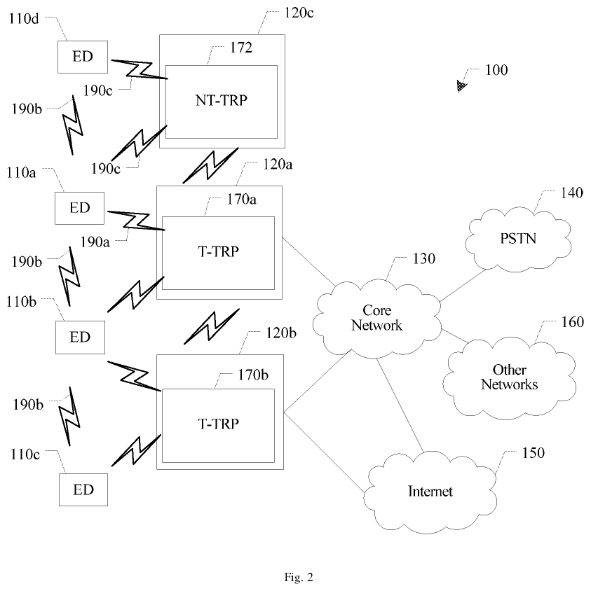

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast, groupcast, unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications, such as earth monitoring, remote sensing, passive sensing and positioning, navigation and tracking, autonomous delivery and mobility, etc., The communication system 100 may provide a high degree of availability and robustness through a joint operation of a terrestrial communication system and a non-terrestrial communication system. For example, integrating a non-terrestrial communication system, or components thereof into a terrestrial communication system can result in what may be considered a heterogeneous network comprising multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a PSTN 140, the Internet 150, and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a, 170b and NT-TRP 172, the Internet 150, the core network 130, the PSTN 140, the other networks 160, or any combination of the preceding. In some examples, ED 110a may communicate an uplink and/or downlink transmission over a terrestrial air interface 190a with T-TRP 170a. In some examples, the EDs 110a, 110b, 110c, and 110d may also communicate directly with one another via one or more sidelink air interfaces 190b. In some examples, ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA, also known as discrete Fourier transform spread OFDMA, DFT-s-OFDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 172 for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANs 120a and 120b or EDs 110a 110b, and 110c or both, and (ii) other networks (such as the PSTN 140, the Internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the Internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), User Datagram Protocol (UDP). EDs 110a 110b, and 110c may be multimode devices capable of operation according to multiple radio access technologies, and incorporate multiple transceivers necessary to support such.

FIG. 3 illustrates another example of an ED 110 and a base station 170a, 170b and/or 170c. The ED 110 is used to connect persons, objects, machines, etc. The ED 110 may be widely used in various scenarios including, for example, cellular communications, device-to-device (D2D), vehicle to everything (V2X), peer-to-peer (P2P), machine-to-machine (M2M), machine-type communications (MTC), internet of things (IoT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, wearable devices (such as a watch, a pair of glasses, head mounted equipment, etc.), an industrial device, or an apparatus in (e.g. communication module, modem, or chip) or comprising the forgoing devices, among other possibilities. Future generation EDs 110 may be referred to using other terms. The base station 170a and 170b is a T-TRP and will hereafter be referred to as T-TRP 170. Also shown in FIG. 3, a NT-TRP will hereafter be referred to as NT-TRP 172. Each ED 110 connected to T-TRP 170 and/or NT-TRP 172 can be dynamically or semi-statically turned-on (i.e., established, activated, or enabled), turned-off (i.e., released, deactivated, or disabled) and/or configured in response to one of more of: connection availability and connection necessity.

The ED 110 includes a transmitter 201 and a receiver 203 coupled to one or more antennas 204. Only one antenna 204 is illustrated to avoid congestion in the drawing. One, some, or all of the antennas 204 may alternatively be panels. The transmitter 201 and the receiver 203 may be integrated, e.g. as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the Internet 150 in FIG. 1). The input/output devices or interfaces permit interaction with a user or other devices in the network. Each input/output device or interface includes any suitable structure for providing information to or receiving information from a user, and/or for network interface communications. Suitable structures include, for example, a speaker, a microphone, a keypad, a keyboard, a display, a touch screen, etc.

The ED 110 includes the processor 210 for performing operations including those operations relate to preparing a transmission for uplink transmission to the NT-TRP 172 and/or the T-TRP 170; those operations relate to processing downlink transmissions received from the NT-TRP 172 and/or the T-TRP 170; and those operations relate to processing sidelink transmission to and from another ED 110. Processing operations relate to preparing a transmission for uplink transmission may include operations such as encoding, modulating, transmit beamforming, and generating symbols for transmission. Processing operations relate to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g. by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g. beam angle information (BAI), received from the T-TRP 170. In some embodiments, the processor 210 may perform operations relating to network access (e.g. initial access) and/or downlink synchronization, such as operations relating to detecting a synchronization sequence, decoding and obtaining the system information, etc. In some embodiments, the processor 210 may perform channel estimation, e.g. using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201, and the processing components of the receiver 203 may each be implemented by the same or different one or more processors that are configured to execute instructions stored in a memory (e.g. in the memory 208). Alternatively, some or all of the processor 210, the processing components of the transmitter 201, and the processing components of the receiver 203 may each be implemented using dedicated circuitry, such as a programmed field-programmable gate array (FPGA), an application-specific integrated circuit (ASIC), or a hardware accelerator such as a graphics processing unit (GPU) or an artificial intelligence (AI) accelerator.

In some embodiments, the ED 110 could be replaced with an apparatus in the ED 110 (The apparatus, for example, is a communication module, a modem, a chip, or a chipset inside the ED 110). It includes at least one processor, and an interface or at least one pin. In this scenario, the transmitter 201 and receiver 203 may be replaced by the interface or at least one pin, wherein the interface or at least one pin is to connect the apparatus (e.g., chip) and other apparatus (e.g., chip, memory, or bus). Accordingly, the transmitting information to T-TRP 170 or NT-TRP 172 may be referred as transmitting information to the interface or at least one pin, and receiving information from T-TRP 170 or NT-TRP 172 may be referred as receiving information from the interface or at least one pin. The information may include control signaling and/or data.

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus in the forgoing devices.

In some embodiments, the parts of the T-TRP 170 may be distributed. For example, some of the modules of the T-TRP 170 may be located remote from the equipment that houses the antennas 256 for the T-TRP 170, and may be coupled to the equipment that houses the antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses the antennas 256 of the T-TRP 170. The modules may also be coupled to other T-TRPs. In some embodiments, the T-TRP 170 may actually be a plurality of T-TRPs that are operating together to serve the ED 110, e.g. through the use of coordinated multipoint transmissions.

The T-TRP 170 includes at least one transmitter 252 and at least one receiver 254 coupled to one or more antennas 256. Only one antenna 256 is illustrated to avoid congestion in the drawing. One, some, or all of the antennas 256 may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to the NT-TRP 172, and processing a transmission received over backhaul from the NT-TRP 172. Processing operations relate to preparing a transmission for downlink or backhaul transmission may include operations such as encoding, modulating, precoding (e.g. multiple input multiple output (MIMO) precoding), transmit beamforming, and generating symbols for transmission. Processing operations relate to processing received transmissions in the uplink or over backhaul may include operations such as receive beamforming, demodulating received symbols, and decoding received symbols. The processor 260 may also perform operations relating to network access (e.g. initial access) and/or downlink synchronization, such as generating the content of synchronization signal blocks (SSBs), generating the system information, etc. In some embodiments, the processor 260 also generates an indication of beam direction, e.g. BAI, which may be scheduled for transmission by a scheduler 253. The processor 260 performs other network-side processing operations described herein, such as determining the location of the ED 110, determining where to deploy the NT-TRP 172, etc.

In some embodiments, the processor 260 may generate signaling, e.g. to configure one or more parameters of the ED 110 and/or one or more parameters of the NT-TRP 172. Any signaling generated by the processor 260 is sent by the transmitter 252. Note that “signaling”, as used herein, may alternatively be called control signaling. Signaling may be transmitted in a physical layer control channel, e.g. a physical downlink control channel (PDCCH), in which case the signaling may be known as dynamic signaling. Signaling transmitted in a downlink physical layer control channel may be known as Downlink Control Information (DCI). Signaling transmitted in an uplink physical layer control channel may be known as Uplink Control Information (UCI). Signaling transmitted in a sidelink physical layer control channel may be known as Sidelink Control Information (SCI). Signaling may be included in a higher-layer (e.g., higher than physical layer) packet transmitted in a physical layer data channel, e.g. in a physical downlink shared channel (PDSCH), in which case the signaling may be known as higher-layer signaling, static signaling, or semi-static signaling. Higher-layer signaling may also refer to Radio Resource Control (RRC) protocol signaling or Media Access Control-Control Element (MAC-CE) signaling.

The scheduler 253 may be coupled to the processor 260. The scheduler 253 may be included within or operated separately from the T-TRP 170. The scheduler 253 may schedule uplink, downlink, sidelink, and/or backhaul transmissions, including issuing scheduling grants and/or configuring scheduling-free (e.g., “configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252, and the processing components of the receiver 254 may each be implemented by the same or different one or more processors that are configured to execute instructions stored in a memory, e.g. in the memory 258. Alternatively, some or all of the processor 260, the scheduler 253, the processing components of the transmitter 252, and the processing components of the receiver 254 may be implemented using dedicated circuitry, such as a programmed FPGA, a hardware accelerator (e.g., a GPU or AI accelerator), or an ASIC.

In some embodiments, the T-TRP 170 could be replaced with an apparatus in the T-TRP (The apparatus, for example, is a communication module, a modem, a chip, or a chipset inside the T-TRP). It includes at least one processor, and an interface or at least one pin. In this scenario, the transmitter 252 and receiver 254 may be replaced by the interface or at least one pin, wherein the interface or at least one pin is to connect the apparatus (e.g., chip) and other apparatus (e.g., chip, memory, or bus). Accordingly, the transmitting information to ED 110 may be referred as transmitting information to the interface or at least one pin, and receiving information from the ED 110 may be referred as receiving information from the interface or at least one pin. The information may include control signaling and/or data.

Although the NT-TRP 172 is illustrated as a drone only as an example, the NT-TRP 172 may be implemented in any suitable non-terrestrial form, such as satellites and high altitude platforms, including international mobile telecommunication base stations and unmanned aerial vehicles, for example. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated to avoid congestion in the drawing. One, some, or all of the antennas may alternatively be panels. The transmitter 272 and the receiver 274 may be integrated as a transceiver. The NT-TRP 172 further includes a processor 276 for performing operations including those relate to: preparing a transmission for downlink transmission to the ED 110s, processing an uplink transmission received from the ED 110s, preparing a transmission for backhaul transmission to T-TRP 170, and processing a transmission received over backhaul from the T-TRP 170. Processing operations relate to preparing a transmission for downlink or backhaul transmission may include operations such as encoding, modulating, precoding (e.g. MIMO precoding), transmit beamforming, and generating symbols for transmission. Processing operations relate to processing received transmissions in the uplink or over backhaul may include operations such as receive beamforming, demodulating received symbols, and decoding received symbols. In some embodiments, the processor 276 implements the transmit beamforming and/or receive beamforming based on beam direction information (e.g. BAI) received from the T-TRP 170. In some embodiments, the processor 276 may generate signaling, e.g. to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272, and the processing components of the receiver 274 may each be implemented by the same or different one or more processors that are configured to execute instructions stored in a memory, e.g. in the memory 278. Alternatively, some or all of the processor 276, the processing components of the transmitter 272, and the processing components of the receiver 274 may be implemented using dedicated circuitry, such as a programmed FPGA, a hardware accelerator (e.g., a GPU or AI accelerator), or an ASIC. In some embodiments, the NT-TRP 172 may actually be a plurality of NT-TRPs that are operating together to serve the ED 110, e.g. through coordinated multipoint transmissions.

The T-TRP 170, the NT-TRP 172, and/or the ED 110 may include other components, but these have been omitted for the sake of clarity.

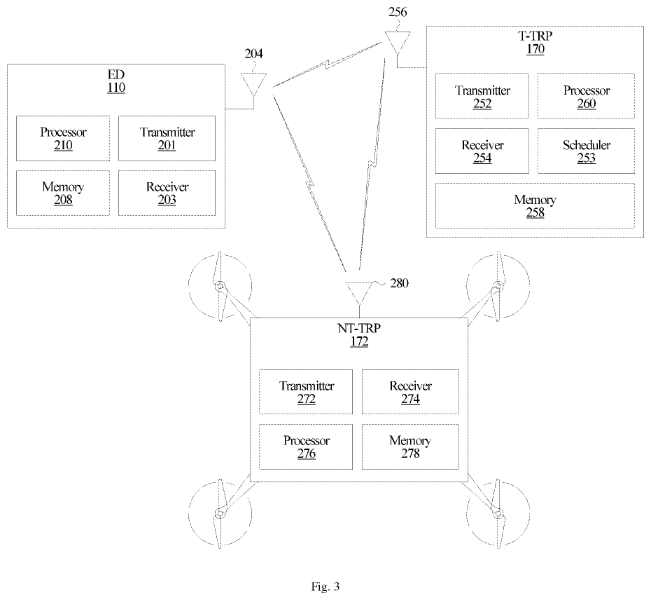

One or more steps of the embodiment methods provided herein may be performed by corresponding units or modules, according to FIG. 4. FIG. 4 illustrates units or modules in a device, such as in the ED 110, in the T-TRP 170, or in the NT-TRP 172. For example, a signal may be transmitted or output by a transmitting unit or by a transmitting module. A signal may be received or input by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be a circuit such as an integrated circuit. Examples of an integrated circuit include a programmed FPGA, a GPU, or an ASIC.

For instance, one or more of the units or modules may be logical such as a logical function performed by a circuit, by a portion of an integrated circuit, or by software instructions executed by a processor. It will be appreciated that where the modules are implemented using software for execution by a processor for example, the modules may be retrieved by a processor, in whole or part as needed, individually or together for processing, in single or multiple instances, and that the modules themselves may include instructions for further deployment and instantiation.

While not shown, the transmitting module and the receiving module may be part of, or combined into, a transceiver module. A transceiver module may also be known as an interface module, or simply an interface, for inputting and outputting operations.

Additional details regarding the EDs 110, the T-TRP 170, and the NT-TRP 172 are known to those of skill in the art. As such, these details are omitted here.

The channel coding module in communications systems encode K source bits into N code bits to provide error correction capability against adversary channel condition such as noise and interference. The code rate is R=K/N. In practice, the code rate R is selected according to channel quality.

Polar codes are capacity-achieving codes and thus a great breakthrough in coding theory. As code length approaches infinity, the synthesized channels become either noiseless or pure noise. The synthesized channels that are also known as subchannels are created by or associated with the polar code. The noiseless subchannels are utilized to transport information, and their proportion is proven to achieve the channel capacity defined by Shannon. The above-mentioned channel polarization phenomenon occurs under successive cancellation (SC) or SC-based decoding, which has a relatively low complexity.

Rate matching is performed after channel encoding, by either puncturing/shortening or repeating some code bits. The purpose of this operation is to obtain a code bit sequence of desired length for transmission over limited channel resources.

Channel interleaving is applied after channel encoding and rate matching by permuting the code bits. The purpose is to provide stable or superior performance under high-order modulation or in a fading channel.

HARQ is a mechanism to provide reliable wireless transmission. It combines forward error correction (FEC) and automatic repeat request (ARQ). In HARQ, the initial transmission is a FEC code word with means (such as cyclic redundancy check (CRC) bits) to support error detection at the receiver. If a decoding error is detected, the receiver will send back a negative acknowledgment (NACK) signaling to inform the transmitter of the error, and request a retransmission. The retransmitted bits can be directly selected from the initially transmitted bits, or incrementally generated code bits which form a longer code word with the initially transmitted bits. The former approach is called chase-combining HARQ (CC-HARQ) and the latter approach is called IR-HARQ. Typically, IR-HARQ outperforms CC-HARQ with the additional coding gain from incremental redundancy.

Polar codes belong to the class of linear block codes. For a polar code of length N, its generator matrix is G_{N}, and its encoding process is

$${x}_{1}^{N} = {u}_{1}^{N} {G}_{N} ,$$

wherein

$${u}_{1}^{N} = [ {u}_{1} , {u}_{2} , … , {u}_{N} ]$$

is the binary information vector,

$${x}_{1}^{N} = [ {x}_{1} , {x}_{2} , … , {x}_{N} ]$$

is the binary code vector. The N×N binary matrix

$${G}_{N} = {F}_{2}^{⊗ n} ,$$

wherein

$${F}_{2} = [ \begin{matrix}1 & 0 \\ 1 & 1\end{matrix} ]$$

is the polarization kernel matrix, n=log₂ N, and ⊗ is Kronecker product.

Typically, there are K information bits to be encoded into N code bits. In some embodiments of the present disclosure, K information bits refer to K source bits. Accordingly, the inequality K<N is given to obtain a code rate R=K/N<1. That implies only part of

$${u}_{1}^{N}$$

is used to carry information bits, and the rest are typically called frozen bits. The information bit set or called information set may be denoted by I, and the frozen bit set, or called frozen set may be denoted by F respectively. In some cases there is an additional parity-check bit set or called PC bit set that is denoted by P. The frozen bits are known (usually all zeros, but may also be other known values or sequences) before decoding, so they do not carry any payload information. The PC bits are parity-check bits generated from a subset of information bits. Therefore, the PC bits are known once the associated information bits are decoded. The decoding of polar codes attempts to recover all information bits.

The transmitted code length M may not always be the power of 2, i.e., M<N. In practice, puncturing and shortening are used to reduce transmitted code bits from N to M. For convenience, the present disclosure hereinafter refers to N as the mother code length, and M as the code length. In particular, punctured bits are non-transmitted bits unknown to the decoder, but shortened bits are non-transmitted bits known to the decoder, and shortened bits are usually all zeros.

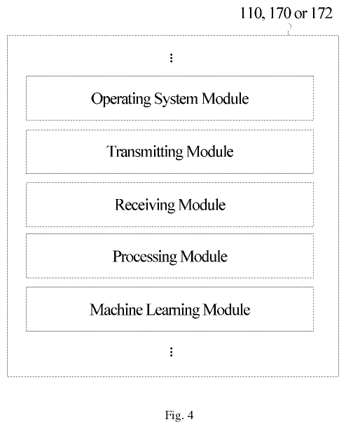

An example of a polar code with N=8, K=4 is shown in the FIG. 5. Each “butterfly” in FIG. 5 represents a polarization, i.e.,

$${x}_{1}^{2} = {u}_{1}^{2} [ \begin{matrix}1 & 0 \\ 1 & 1\end{matrix} ] .$$

In this example, the information set is I={u₄, u₆, u₇, u₈}, and the frozen set is F={u₁, u₂, u₃, u₅}.

Successive cancellation (SC) is the basic decoding algorithm for polar codes, where all the frozen bits and information bits are decoded sequentially, i.e., bit by bit. The preceding bits are typically always decoded first.

Successive cancellation list (SCL) is an enhanced decoding algorithm for polar codes, where multiple (e.g., a number L) SC decoding instances are executed. Each instance is called a “decoding path”. When decoding each binary bit, both “o” and “1” branches are extended to each path, creating 2L paths. Then, all 2L paths are compared, where the most likely L paths are kept, and the least likely L paths are discarded or pruned. These path extension and pruning operations are performed during decoding of every information bit, until all information bits are decoded. At last, the most likely path is selected as the decoding output.

CRC-aided successive cancellation list (CA-SCL) works almost the same as SCL, except that in the last step, the most likely path that passes CRC check is selected as the decoding output.

Parity-check successive cancellation list (PC-SCL) works almost the same as SCL, except that when decoding parity-check (PC) bits, the parity check value of associated preceding bits is used as the bit decision result. PC bits may be considered a type of bit in addition to frozen bits and information bits.

Rate-compatible polar coding is a desirable technology for wireless applications. In one example of polar code rate matching, a combination of puncturing, shortening and repetition is used together with a fixed reliability sequence to balance performance and complexity. In particular, subblock-wise interlacing and interleaving is used for both puncturing and shortening. The puncturing and shortening patterns are symmetric.

With mother code length N, and the transmitted code length M, the specific rate matching scheme used is Repetition, when M>N; Puncturing, when K/M≤7/16; Shortening, when K/M>7/16;

A subblock-wise interleaving is performed before puncturing and shortening. The interleaver partitions the length-N mother code into 32 subblocks of size N/32 and interlaces them. An example interleaver scheme is shown in FIG. 6, which is reproduced from a 3GPP standard specification.

Since puncturing is performed from the 1st code bit of a code word, and shortening is performed from the last code bit, the rate matching module is efficiently implemented through a cyclic buffer. And a code word also refers to a code bit, a coded bit, or an encoded bit. All mother code bits are placed in the cyclic buffer, and puncturing is done by selecting the bits in clockwise order, and shortening is done by selecting bits in counter-clockwise order.

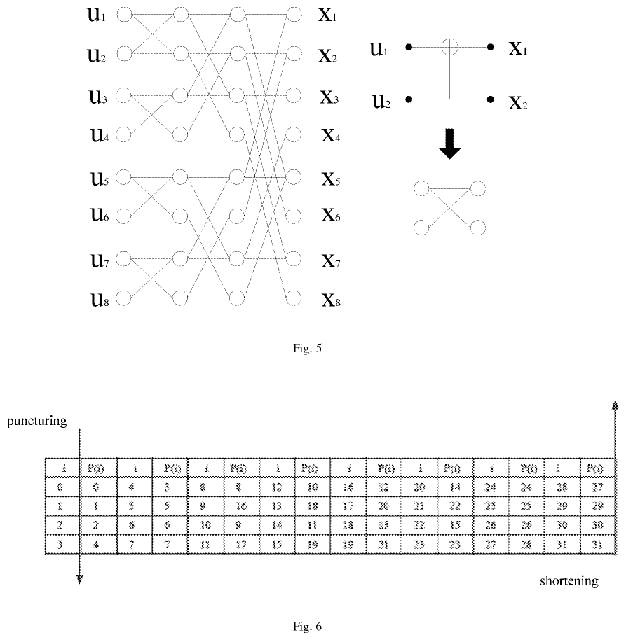

FIG. 7 is a diagram illustrating puncturing and shortening with a cyclic buffer. At 602 in FIG. 7, code bits of a code word are illustrated in a vertical column, with punctured and shortened bits as shown. At 604, FIG. 7 illustrates a cyclic buffer, represented by a circle shape, and reading of code bits with no puncturing or shortening. The next two circles illustrate, respectively, cyclic buffers with dashed lines representing puncturing from the beginning of the buffer at 606 and shortening from the end of the buffer at 608.

Another polar code rate matching example involves an incremental freezing HARQ method, wherein transmissions of multiple short code words are supported. As more short codes are transmitted, the overall code length increases, and the overall code rate decreases.

In the first transmission, an (M1, K) polar code is constructed, encoded and transmitted. M1 is the first transmitted code length, K is the number of the first transmitted information bits. The first code rate is R1=K/M1. Usually, the code rate is determined such that R1<C1, wherein C1 is the channel capacity of the first transmission. But in the case of faded channel or inaccurate channel estimation, there may be the inequality R1>C1, and decoding will fail and a second transmission is required.

In the second transmission, K2 least reliable information bits are selected from the K information bits in the first transmission. In practice, K2 is chosen according to the estimated channel capacity of the second transmission. An (M2, K2) polar code is constructed accordingly and encoded and transmitted. M2 is the second transmitted code length, K2 is the number of the second transmitted information bits. However, if R2>C2, and decoding will fail again and a third transmission is required. The third and fourth transmissions are constructed similarly, and so on.

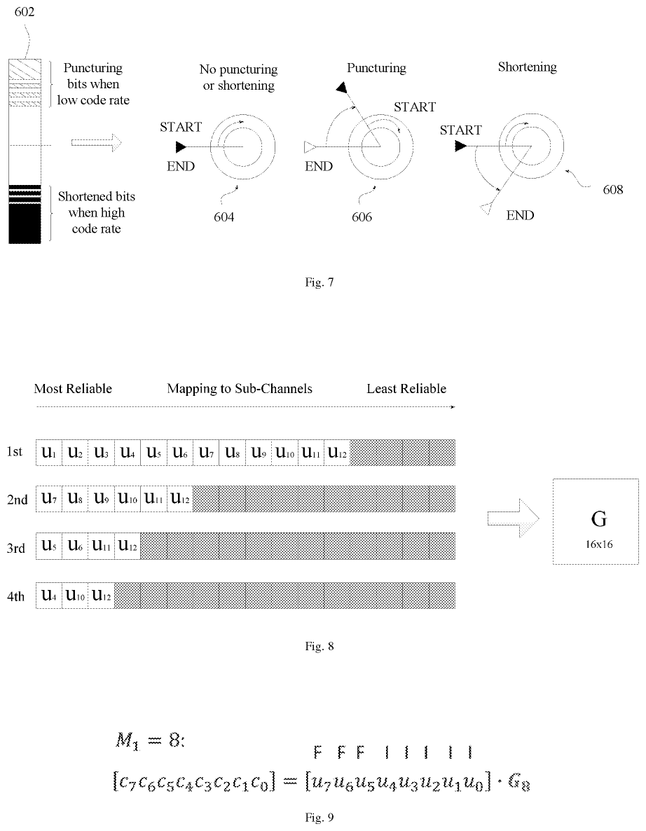

At the receiver side, the decoder should always decode the last received code word, because it has the lowest code rate and thus the best chance of successful decoding. After the last transmission is correctly decoded, the corresponding information bits in all previous transmissions become known, and can be decoded as frozen bits with known values. This process is repeated as more code words are decoded, until all K bits in the first transmission is decoded. The term “incremental freezing” refers to the operations to additionally freeze some information bits in the previous transmissions once a later transmitted code word is decoded. FIG. 8 shows an example of the encoding process for 4 transmissions, wherein M1=M2=M3=M4=16, and K1=12, K2=6, K3=4, K4=3. M3 is the third transmitted code length, M4 is the fourth transmitted code length, K3 is the number of the third transmitted information bits, and K4 is the number of the fourth transmitted information bits.

Parity-check (PC) polar codes may be used to improve the minimum code distance of the original polar codes. Values of PC bits are determined by their preceding information bits, and specifically, binary linear combinations of a subset of preceding information bits. In one proposal of PC polar codes to support IR-HARQ, the PC bits are used to couple multiple retransmissions into a longer polar code with extra coding gain.

The PC functions currently used for IR-HARQ are also a special case, wherein some information bits are copied from the initial transmitted code block to a retransmitted code block. This one-to-one parity checking between the two shorter code blocks effectively couples the two code blocks into a longer code block.

For example, the initial transmission is a (M1=8, K=5) polar code, wherein {u0, u1, u2, u3, u4} is the information set, and {u5, 6, u7} is the frozen set. Its encoding process is shown in FIG. 9. In this example, bit indices are in decreasing order of reliability.

In the first retransmission, four additional code bits are transmitted. These four bits are coupled with the initially transmitted 8 bits to form a (M2=12, K=5) polar code. The coupling is achieved by copying the value of u4 to u8 during encoding, thus generating a PC function u4+8=0, or equivalently a PC function u8=u4. As said, the largest index in this PC function corresponds to the PC bit (here u8). During decoding, u4 decoded as an information bit, while u8 is decoded as a PC bit using u8=u4. With {u0, u1, u2, u3, u8} as the information set, {u4} as the PC set, and {u5, u6, u7, u9, u10, u11} as the frozen set, the encoding process is shown in FIG. 10.

In the second retransmission, the remaining four bits c12, c13, c14, c15 are transmitted to form a (M3=16, K=5) polar code. But no new PC bits are generated.

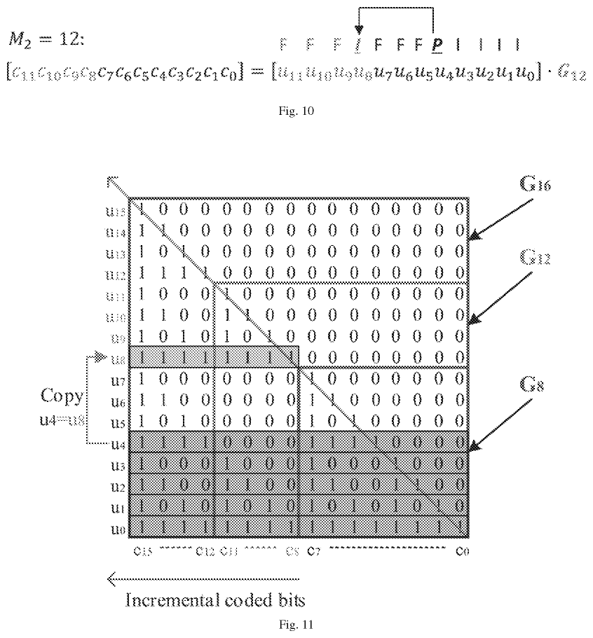

From the polar transform matrix point of view, the three transmissions with effective code lengths M1=8, M2=12, M3=16, are showed in FIG. 11.

Because a polar code with arbitrary length is always rate matched from a mother polar code of length 2ⁿ, wherein n is a non-negative integer, determining the mother code length is a crucial step in the encoding chain of polar codes.

An example polar coding scheme for determining mother code length is as follows. An example of the pseudocodes of the current mother code length calculating method is shown below:
Denote by E the rate matching output sequence length;

If E ≤ (9/8) · 2^{(┌log}^{₂}^{E┐-1)}and K/E < 9/16
n₁ = ┌log₂E┐ − 1;
else
n₁ = ┌log₂E┐;
end if
Rₘᵢₙ = 1/8;
n₂ = ┌log₂(K/Rₘᵢₙ)┐;
n = max{min{n₁,n₂,nₘₐₓ},nₘᵢₙ},

wherein nₘᵢₙ=5. E is the rate matching output sequence length, which refers to the transmitted code length M. K is the number of the information bits. Rmin is the minimum code rate, nmin is the minimum mother code length Nmin in logarithm domain, nmax is the maximum mother code length Nmax in logarithm domain, n1 is a first stage mother code length N1 in logarithm domain, n2 is a second stage mother code length N2 in logarithm domain.

In summary, the principles for determining mother code length are:
1. The mother code length should be larger than the rate matching output sequence length to allow for puncturing or shortening.
2. The mother code length should be no larger than the maximum mother code length.
3. The mother code length should be no larger than twice the rate matching output sequence length to avoid too much puncturing or shortening.
4. The mother code length should be no smaller than the minimum mother code length.
5. The mother code rate should be no smaller than the minimum code rate, wherein the mother code rate is defined by K/N, N is the mother code length.

The polar coding examples described above have only one mother code length, or determine the mother code length for only one transmission. However, this mother code determination scheme cannot be applied for polar code with retransmissions, or with multiple redundancy versions:

If the mother code length is only designed for an initial transmission, the length does not consider the possibility of potential retransmissions, which requires a longer mother code. And In examples with only one mother code length, additional different mother code lengths will need to be defined for multiple transmissions or multiple redundancy versions.

In order to support potential retransmissions, e.g., incremental-redundancy HARQ, some embodiments of the present disclosure extend the mother code length to be more than twice the rate matching output sequence length. On the one hand, the mother code length needs to be increased based on current design to allow one or more retransmissions; on the other hand, the mother code length cannot exceed certain value for low complexity consideration.

The following descriptions are some detailed examples of polar codes for present disclosure.

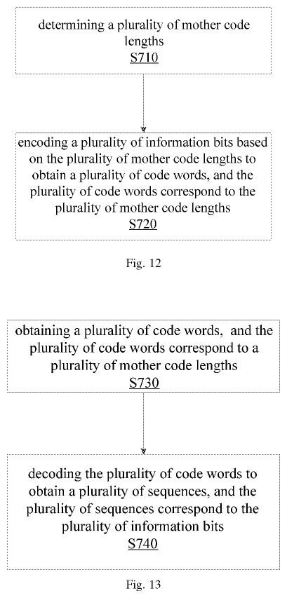

Referring to FIG. 12, as an illustrative example without limitation, a simplified flow illustration of the encoding method is provided.

As shown in FIG. 12, the encoding method includes the following steps 710 and 720. The executing entity of the encoding method may be a device or an apparatus in the device, wherein the device or the apparatus may include an encoder of polar codes. In some embodiments the apparatus may be a communication module, a modem, or a chip in the device.

Step 710, determining a plurality of mother code lengths.

In the embodiments of the present disclosure, the scenarios that at least a retransmission is required or a plurality of redundancy versions are transmitted in a certain transmission are considered in encoding process. Therefore a plurality of mother code lengths are needed to be determined based on the communications systems.

In some embodiments, the plurality of mother code lengths could be determined based on the number of retransmissions or redundancy versions. And in some embodiments, determining a plurality of mother code lengths may be based on at least one parameter of the followings, such as a minimum code rate, a maximum code rate, a minimum mother code length, a maximum mother code length, a rate matching output length, an index of redundancy version, a transmission index, a number of transmissions or a self-decodable indicator.

Step 720, encoding a plurality of information bits based on the plurality of mother code lengths to obtain a plurality of code words, wherein the plurality of code words correspond to the plurality of mother code lengths.

In some embodiments, a plurality of sequences may be obtained according to the plurality of mother code lengths, and a plurality of information bit sets may be obtained according to the plurality of sequences. In the encoding process, the plurality of information bit sets may be encoded to a new sequence, which corresponds to a plurality of code words.

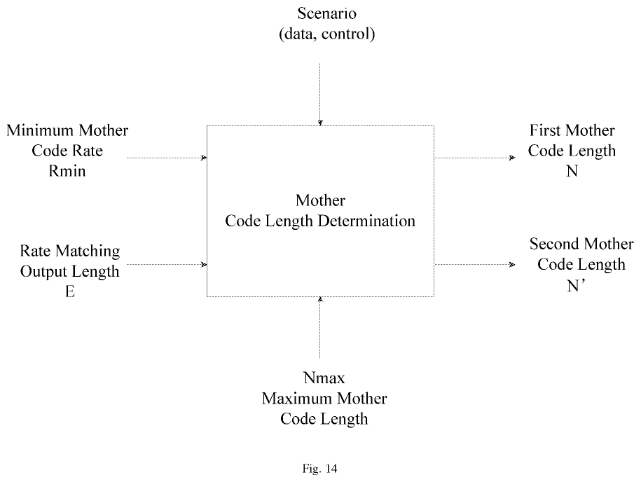

In FIG. 13 as an illustrative example without limitation, a simplified flow illustration of the decoding method is provided. As shown in FIG. 13, the decoding method includes the following steps 730 and 740. The executing entity of the decoding method may be a device or an apparatus in the device, wherein the device or the apparatus may include a decoder of polar codes. In some embodiments the apparatus may be a communication module, a modem, or a chip in the device.

Step 730, obtaining a plurality of code words, and the plurality of code words correspond to a plurality of mother code lengths.

In some embodiments, before decoding, the plurality of code words may be converted to a plurality of first sequences by demodulation or other ways. In the embodiments of the disclosure, no specific limitation is imposed on the ways of obtaining the plurality of first sequences.

In some embodiments, a number of the plurality of first sequences is related to at least one of the followings: a number of redundancy versions, a number of transmission times, and a self-decodable indicator. The number of the plurality of first sequences is related to the number of the plurality of code words. And the number of the plurality of code words is related to a number of the plurality of mother code lengths. In some embodiments, different number of the plurality of mother code lengths may be determined with different number of redundancy versions, different number of transmission times, or different self-decodable indicator. In some embodiments, the flexible decoding process may be executed according to the number of the plurality of first sequences, and the communication systems may be able to support multiple scenarios with different transmission times or redundancy versions, which is very useful and convenient in transmission process.

Step 740, decoding the plurality of code words to obtain a plurality of sequences, and the plurality of sequences correspond to the plurality of information bits.

In some embodiments, SCL algorithm may be operated during the decoding process. Then after CRC process, the device may output the plurality of sequences including the plurality of information bits. In some embodiments, another algorithm and technique may be used in decoding. In the embodiments of the disclosure, no specific limitation is imposed on the algorithm and technique in decoding.

Some embodiments of the present disclosure may provide methods of determination of mother code lengths for polar codes in scenarios in which longer or multiple mother codes may be required.

Methods of determination of mother code lengths for polar codes are introduced in details below.

In order to support multiple redundancy versions or aggregations levels, some embodiments of the present disclosure specify multiple mother code lengths.

Some example methods of determining polar mother code length include the following features:

In these cases the schemes of polar codes include at least one extended mother code length:

In some embodiments, methods of determination of mother code length may be based on the fixed mother code length extension. An extended mother code length may be obtained based on the current calculated mother code length. For example the extended mother code length may be obtained by multiplying the current calculated mother code length by a fixed number of extension times. The fixed number of extension times is one of the factors used to determining mother code length. The extended mother code length is related to retransmissions, redundancy versions, or other scenarios.

At this time methods of determination of mother code length include the following features of the fixed number of extension times:

The fixed number of extension times is pre-defined in a standard.

The fixed number of extension times is signaled by DCI or configured in RRC.

In some embodiments the fixed number of extension times may be obtained by the transmitters though several ways, such as signaling the transmitters by DCI, configuring in RRC and so on. In the embodiments of the disclosure, no specific limitation is imposed on the ways transmitting the number of fixed extension times.

The fixed number of extension times is related to device capability, which can be derived from other non-channel-coding parameters.

The fixed number of extension times is related to uplink or downlink, and/or traffic type (e.g., data channel, control channel).

The fixed number of extension times is related to communication scenario (e.g., Enhanced Mobile Broadband (eMBB), Ultra-Reliable Low-Latency Communications (URLLC)).

The fixed number of extension times can be 2, 4, 8, 16 or larger. I.e., it is a power-of-2 integer.

In some embodiments the fixed number of extension times is related to an index of redundancy version, a transmission index, a number of transmissions and so on, which means the fixed number of extension times may or may not be the same in the different transmission or the different index of redundancy version of polar codes. In the embodiments of the disclosure, no specific limitation is imposed on the value of the fixed number of extension times.

In some embodiments, methods of determination of mother code length may be based on a maximum mother code length. No matter what the current calculated mother code length is, the current calculated mother code length may be extended until it reaches the maximum mother code length, or the extended mother code length may be fixed to the maximum mother code length. The maximum mother code length is one of the factors used to determining mother code length.

At this time methods of determination of mother code length include the following features of the maximum mother code length:
The maximum mother code length is pre-defined in a standard;
The maximum mother code length is signaled by DCI or configured in RRC;
The maximum mother code length is related to device capability, which can be derived from other non-channel-coding parameters;
The maximum mother code length is related to uplink or downlink, and/or traffic type (e.g., data channel, control channel);
The maximum mother code length can be 2, 4, 8, 16 or larger. I.e., it is a power-of-2 integer.

Then, considering both the above two factors, methods of determination of mother code lengths may include at least one of the following:

The first aspect is modifying the current mother code length calculating method, such that the parameter “the fixed number of extension times” is included, and thus mother code extension is taken into consideration when determining the extended mother code length. At this time the method of determination of mother code lengths ensures that the extended mother code length does not exceed the maximum mother code length; otherwise, the fixed number of extension times may set to be a fixed value according to features of the fixed number of extension times.

The second aspect is keeping the current mother code length calculating formula, which does not involve the parameter “the fixed number of extension times”, but decides whether to extend the current calculated mother code by the fixed number of extension times according to the features of the fixed number of extension times or fewer times. If the extended mother code length does not exceed the maximum mother code length, then do nothing. Otherwise, reduce the number of extension times until the maximum mother code length is not exceeded. [Note that the two aspects may lead to different current calculated mother code lengths which are obtained with different methods. (e.g., the current calculated mother code lengths are related to the initial transmission or retransmissions).

In these cases the schemes of polar codes with multiple mother code lengths are as follows:

1. In the case that the multiple mother code lengths include a mother code length for an initial transmission and an extended mother code length for all retransmissions:

Two mother code lengths are defined. One is shorter, called the initial mother code length, for initial transmission; and the other is longer, called the extended mother code length, for all the possible retransmissions. Note that the longer extended mother code length includes the initial mother code length.

One short mother code length is defined (e.g., using the method in methods of determination of mother code length based on the fixed mother code length extension), and the longer mother code length is defined with respect to the short mother code length.

The longer mother code length is defined (e.g., using the method in methods of determination of mother code length based on a maximum mother code length), and the short mother code length is defined with respect to the longer mother code length.

Two mother code lengths are defined at the same time (e.g., using the method in methods of determination of mother code length based on the fixed mother code length extension and methods of determination of mother code length based on a maximum mother code length).

2. In the case that the multiple mother code lengths include a mother code length for each of the retransmissions, or each of the redundancy versions:

Using this definition, the mother code length for each transmission and retransmission are separately defined. And one mother code length does not include another mother code length.

In some scenarios, the retransmissions opportunities are pre-defined or pre-scheduled, i.e., without the need to request a retransmission using NACK. This is called blind retransmission. In this case, the mother code length can be the same for each retransmission (or redundancy version) for simplicity, or monotonically increasing for higher reliability, or monotonically decreasing for higher spectrum efficiency.

FIG. 14 is a block diagram of methods of determination of mother code lengths. In FIG. 14, the first mother code length refers to the short mother code length, such as the initial mother code length for the initial transmission. And the second mother code length refers to the longer mother code length, such as the mother length for retransmissions. In some embodiments, the short mother code length and the longer mother code length may relate to different redundancy version.

Control channel, also known as CC, is mainly used for transmitting signaling or synchronizing data in multi-channel shared communication systems. In analog cellular systems, it mainly consists of paging and access channels. In digital cellular systems, it mainly consists of broadcast channels, public control channels, and dedicated control channels. Data channel is the key to the flexibility of mobile communication systems and the introduction of new services. Data channels can provide high-speed data transmission services for mobile users. Control channel will provide high-speed signaling transmission services for network management and introduce new business services such as integrated digital services.

In scenario of data channel encoding or control channel encoding, the initial mother code length and the mother code length for retransmissions may be obtained according to the minimum mother code rate Rmin, the rate matching output length E, and the maximum mother code length. In some embodiments of the present disclosure, the mother code length of data channel and control channel are different, which means the initial mother code length of data channel is different from that of control channel, and the extended mother code length for retransmissions of data channel is different from that of control channel. In some embodiments of the present disclosure, the mother code length of data channel is longer than that of control channel, which means the initial mother code length of data channel is longer than that of control channel, and the extended mother code length for retransmissions of data channel is longer than that of control channel.

In some embodiments the number of mother code lengths and the order of determination of mother code lengths may be different in different situations. The principles of methods of determination of mother code lengths in different situations are as follows:

In the first situation, in the case of “optional retransmission”, which means that retransmissions may not occur, the initial mother code length for the initial transmission may be determined first. Therefore in the subsequent retransmissions, mother code lengths for retransmissions may be determined based on the initial mother code length. For example, mother code lengths for retransmissions may be obtained by multiplying the initial transmission mother code length with the first coefficient. And mother code length for different retransmission may relate to different value of the first coefficient. In some embodiments the mother code length for retransmission refers to the extended mother code length.

In the second situation, in the case of “forced retransmission”, which means that at least one retransmission will definitely occur, at least one mother code length for retransmission may be determined first. And the initial mother code length may be obtained depend on the mother code length for retransmission. For example, the initial mother code length may be obtained by dividing the mother code length for retransmission with the first coefficient. Other mother code lengths for retransmissions may also be determined depend on the mother code length for retransmission. For example, other mother code lengths for retransmissions may be obtained by multiplying the mother code length for retransmission with different values of the first coefficient.

In the third situation, if transmission resources need to be pre-allocated, the reference mother code length will be determined first. And mother code lengths for transmissions (including the initial transmission and retransmissions), or redundancy versions could be obtained based on the reference mother code length. For example, the initial mother code length, each of mother code lengths for retransmissions, or each of mother code lengths for redundancy versions may be obtained by dividing the reference mother code length with different values of the first coefficients.

In some embodiments, there may be some other principles of methods of determination of mother code lengths in other situations. In the embodiments of the disclosure, no specific limitation is imposed on the principles of methods of determination of mother code lengths in other situations.

In some embodiments, the extended mother code length may be obtained based on the first stage mother code length N1, the second stage mother code length N2 and the third stage mother code length N3.

The first stage mother code length may be calculated according to the rate matching output sequence length E, the number of the information bits K to be encoded, a minimum code rate Rmin, a minimum mother code length Nmin, and a maximum mother code length Nmax. Note that the rate matching output sequence length may specifically be the length for the initial (first) transmission, or the first redundancy version (with rvid=0).

Specifically, a few quantities may be defined beforehand:

The first stage mother code length N1 is determined in any of the following ways:

In the first case, the first stage mother code length N1 is the smallest power-of-2 integer which is larger than (or no smaller than) the rate matching output length E.

In the second case, the first stage mother code length N1 is the largest power-of-2 integer which is smaller than (or no larger than) the rate matching output length E.

The minimum code rate (or minimum mother code rate) Rmin is determined in any of the following ways:

The value of the minimum code rate may be pre-defined in standard specification, e.g., 3/4, 2/3, 1/2, 2/5, 1/3, 1/4, 1/5, 1/6, 1/7, 1/8, 1/9, 1/10, 3/32, 1/12, 1/16, 1/32, 1/64.

The value of the minimum code rate may be determined depends on traffic or services types, e.g., 3/32 for low-power devices such as for Massive Machine Type Communication (mMTC) or Internet of Things (IoT), and 1/9 for sidelink traffic and downlink control information, and 1/6 or 1/8 for uplink control information, and 1/3 or 1/4 for eMBB data traffics, and 3/4 or 1/2 for immersive data traffic (high throughput up to 1 Tbps).

The value of the minimum code rate may be flexibly configured through RRC or other means, by a base station to adapt to a situation.

The second stage mother code length N2 is determined in any of the following ways:

In the first case, the second stage mother code length N2 is the smallest power-of-2 integer which leads to a mother code rate, defined as K/N2, is smaller than (or no larger than) the minimum code rate Rmin.

In the second case, the second stage mother code length N2 is the largest power-of-2 integer which leads to a mother code rate, defined as K/N2, is larger than (or no smaller than) the minimum code rate Rmin.

The maximum mother code length Nmax is determined in any of the following ways:

The value of the maximum mother code length Nmax may be pre-defined in standard specification, e.g., 64, 128, 256, 512, 1024, 2048, 4096, 8192, 16384, 32768.

The value of the maximum mother code length Nmax may be the same as the length of a nested reliability sequence of the polar code.

In some embodiments the nested reliability sequence of the polar code that defined the reliability of each subchannel may or may not be set in the standard. In the embodiments of the disclosure, no specific limitation is imposed on the nested reliability sequence of the polar code.

The value of the maximum mother code length may be depends on traffic or services types, e.g., 128 for low-power devices such as for mMTC or IoT, and 512 for sidelink traffic and downlink control information, and 1024 for uplink control information, and 4096 or 8192 for eMBB data traffics, and 1024 or 2048 for immersive data traffic (high throughput up to 1 Tbps).

The value of the maximum mother code length may be flexibly configured through RRC or other means, by a base station to adapt to a situation.

The minimum mother code length Nmin is determined in any of the following way:

The value of the minimum mother code length may be pre-defined in standard specification, e.g., 16, 32, 64, 128.

The value of the minimum mother code length may depend on traffic or services types, e.g., 16 for low-power devices such as for mMTC or IoT, and 32 for sidelink traffic and downlink control information, and 64 for uplink control information, and 128 or 256 for eMBB data traffics, and 32 or 64 for immersive data traffic (high throughput up to 1 Tbps).

The value of the minimum mother code length may be flexibly configured through RRC or other means, by a base station to adapt to a situation.

With the above quantities, there are several different methods to determine the mother code lengths (including the mother code lengths related to the initial transmission, retransmissions and different redundancy versions):

Step 1a-2a of the first method of determination of mother code lengths is described below.

Step 1a, determining the minimum of N1, N2 and a pre-defined value N3, i.e., N′=min{N1, N2, N3}.

Wherein the pre-defined value N3 can be independent from Nmax, e.g., N3=512.

Or the pre-defined value N3 can be derived from Nmax, e.g., N3=Nmax/2, N3=Nmax/4, or N3=Nmax×2.

Step 2a, determining the first current calculated mother code length Na by determining the maximum between the above minimum in step 1a and Nmin, i.e., N=max{N′, Nmin}. In some embodiments, the initial mother code length and the extended mother code length may be obtained based on the first current calculated mother code length Na.

For example, the extended mother code length may be equal to the current calculated mother code length Na. Or the extended mother code length may be equal to the first current calculated mother code length Na multiplied by the fixed number of extension times. The initial mother code length may be equal to the current calculated mother code length Na. Or the initial mother code length may be equal to the first current calculated mother code length Na multiplied by a constant.

In the embodiments of the disclosure, no specific limitation is imposed on the method of obtaining the initial mother code length and extended mother code length based on the first method.

An example of the pseudocodes of the first method are below (in logarithm domain, e.g., n=log 2N).

n₁=┌log₂ E┐;

n₂=┌log₂(K/Rₘᵢₙ)┐;

n₃=nₘₐₓ−1;

nₐ=max{min{n₁,n₂,n₃},nₘᵢₙ}.

Wherein, n3 is a third stage mother code length N3 in logarithm domain, na is the first current calculated mother code length in logarithm domain.

Step 1b-3b of the second method of determination of mother code lengths is described below.

Step 1b, determining the minimum of N1, N2 and Nmax, i.e., N′=min{N1, N2, Nmax}

Step 2b, determining the initial mother code length Nini as the maximum between the above minimum in step 1b and Nmin, i.e., Nini=max{N′, Nmin}.

Step 3b, determining the extended mother code length Nest by multiplying the above length Nini by C, i.e., Nest=C×Nini, where C is constant power-of-two value specified in standard, e.g., C=2, C=4, C=8, C=16. C is the fixed number of extension times.

Wherein C depends on the channel type, e.g., C=2 for downlink and C=4 for uplink, or C=1 for downlink and C=2 for uplink; or C=1 for control signals and C=2 for data traffic.

In the logarithm domain, multiple by C is equivalent to add c=log 2C, e.g., Nest=C×N is equivalent to nest=c+n. nest is the extended mother code length in logarithm domain.

An example of the pseudocodes of the second method are below (in logarithm domain, e.g., n=log 2N):

n₁=┌log₂ E┐;

n₂=┌log₂(K/Rₘᵢₙ)┐;

nᵢₙᵢ=max{min{n₁,n₂,nₘₐₓ},nₘᵢₙ};

nₑₛₜ=1+nᵢₙᵢ.

Step 1c-3c of the third method of determination of mother code lengths is described below.

Step 1c, determining the minimum of N1, N2 and Nmax, i.e., N′=min{N1, N2, Nmax}.

Step 2c, determining the current calculated mother code length, or called the initial mother code length, as the maximum between the above minimum in step 1c and Nmin, i.e., Nini=max{N′, Nmin}.

Step 3c, determining the extended mother code length Nest using a fixed value. Wherein the fixed value can be the maximum mother code length Nmax.

Wherein the fixed value can be a pre-defined mother code length, which can be either independent from Nmax, or derived from Nmax, e.g., Nest=Nmax/2, or Nest=Nmax×2.

An example of the pseudocodes of the third method are below (in logarithm domain, e.g., n=log 2N):

n₁=┌log₂ E┐;

n2=┌log₂(K/Rₘᵢₙ)┐;

n″=max{min{n₁,n₂,nₘₐₓ},nₘᵢₙ};

nₑₓ=12.

Step 1d-3d of the fourth method of determination of mother code lengths is described below.

Step 1d, determining the minimum of N1, N2 and Nmax, i.e., N′=min{N1, N2,

### Nmax}.

Step 2d, determining the current calculated mother code length, or called the initial mother code length Nini as the maximum between the above minimum in step 1d and Nmin, i.e., N″=max{N′, Nmin}.

Step 3d, determining the extended mother code length Nest by multiplying the initial mother code length Nini by a fixed value, i.e., Nest=C×N″, which should be also no larger than the maximum mother code length.

Wherein C is constant power-of-two value specified in standard, e.g., C=2, C=4, C=8, C=16.

Wherein C depends on the channel type, e.g., C=2 for downlink and C=4 for uplink, or C=1 for downlink and C=2 for uplink; or C=1 for control signals and C=2 for data traffic.

In the logarithm domain, a constant multiplied by C is equivalent to add c, wherein c=log 2C, e.g., Nest=C×Nini is equivalent to n=c+n″.

If the extended mother code length obtained by the above method is larger than Nmax, it will be set to Nest=Nmax.

An example of the pseudocodes of the fourth method are below (in logarithm domain, e.g., n=log 2N):

n₁=┌log₂ E┐;

n₂=┌log₂(K/Rₘᵢₙ)┐;

nᵢₙᵢ=max{min{n₁,n₂},nₘᵢₙ}

nₑₓₜ=min{1+n″,nₘₐₓ}

Note that all the above four methods can be represented in the logarithm domain.

The following description is the detailed introduction of the principles of methods of determination of mother code lengths for polar codes in different situations.

In some embodiments of the present disclosure, the mother code length may be defined according to a different order of determination. For example, in the HARQ retransmission scenario, some retransmissions are optional, while some others are mandatory.

In the first situation, corresponding to the “optional retransmission” case, a mother code length is defined for initial transmission, but an extended mother code length may not need to be defined for retransmission(s). In this case, the initial mother code length is preferentially defined first, and then an extended mother code length that is derived from the initial mother code length is defined later.

Denote by Nini the initial mother code length, and Nest the extended mother code length, the method of the first situation can be described as:
Determine the initial mother code length Nini.
use any of the information described in methods of determination of the extended mother code lengths for polar codes to obtain Nini
Derive the extended mother code length Nest from Nini
Nest=f(Nini), where f(⋅) is a function that can be multiplied by a constant, where in some cases the constant can be a power-of-2 integer.

The pseudocodes of the method in the first situation are below (in logarithm domain, e.g., n=log 2N):

n₁=┌log₂ E┐;

n₂=┌log₂(K/Rₘᵢₙ)┐;

n₃=nₘₐₓ−1;

nᵢₙᵢ=max{min{n₁,n₂,n₃},nₘᵢₙ}

nₑₓₜ=nᵢₙᵢ+1

In some embodiments the pseudocodes of the method in the first situation is an example according to the description of the method of the first situation, which means values of n1, n2, n3, nini, nest may be different in other pseudocodes of the method in the first situation.

In the second situation, corresponding to the “mandatory retransmission” case, both a mother code length for initial transmission and an extended mother code length for retransmission(s) are defined. In this case, the longer extended mother code length may be defined first, and then the partial length corresponding to the initial transmission is specified.

Using the same definition of Nini and Nest, the method of the second situation can be described as:
Determine the extended mother code length Nest
use any of the methods described in methods of determination of mother code lengths for polar codes to obtain Nest
Derive the initial mother code length Nini from Nest
Nini=f(Nest), where f(⋅) is a function that can be divided by a constant, where in some cases the constant can be a power-of-2 integer.

The pseudocodes of the method in the second situation are below (in logarithm domain, e.g., n=log 2N):

n₁=┌log₂ E┐;

n₂=┌log₂(K/Rₘᵢₙ)┐;

n″=max{min{n₁,n₂},nₘᵢₙ}

nₑₓₜ=min{1+n″,nₘₐₓ}

nᵢₙᵢ=nₑₓₜ−1

Note that all the above methods in the present disclosure can be represented in the logarithm domain.

In some embodiments the pseudocodes of the method in the second situation is an example according to the description of the method of the second situation, which means values of n1, n2, n3, nini, nest may be different in other pseudocodes of the method in the second situation.

In the third situation, the mother code length of multiple retransmissions (or redundancy versions) can be determined all at once. For example, in some so-called blind retransmission cases, the resources for retransmissions are pre-allocated. Therefore, the mother length of each retransmission can also be pre-determined.

Specifically, the reference mother code length Nref can be defined, and then several mother code lengths for each (re) transmission Nrv0, Nrv1, Nrv2, Nrv3 . . . can be defined with respect to Nref. Steps are as follows:
1. Determining the reference mother code length Nref by using any of the methods described in methods of determination of mother code lengths for polar codes.
2. Deriving the mother code lengths Nrv0, Nrv1, Nrv2, Nrv3 . . . for each redundancy version.

Nrv0=f0(Nref), Nrv1=f1(Nref), Nrv2=f2(Nref), Nrv3=f3(Nref), . . . , wherein f0(⋅), f1(⋅), f2(⋅) and f3(⋅) are functions that can be either multiplied by a constant or divided by a constant. Here the constants can be power-of-2, but in some cases can also be “power-of-2 minus 1”, or the difference between two different power-of-2 integers.

In the first example there are two transmissions, including an initial transmission and a retransmission. If the reference mother code length Nref is 1024, the mother code lengths for each transmission can be set using the following options:
Option A: Nrv0=Nref=1024; Nrv1=Nref=1024;
Option B: Nrv0=Nref=1024; Nrv1=Nref/2=512; (or Nrv0=Nref=512; Nrv1=Nref/2=256).

If the reference mother code length Nref is 512, the mother code lengths for each transmission can be set using the following options:
Option C: Nrv0=Nref=512, Nrv1=2×Nref=1024;
Option D: Nrv0=Nref=512, Nrv1=3×Nref=1536.

In the second example there are four transmissions, including an initial transmission and three retransmissions (or a subset of the three retransmissions). If the reference mother code length Nref is 512, the mother code lengths for each transmission can be set using the following options:
Option A: Nrv0=Nref=512; Nrv1=Nref=512; Nrv3=Nref=512; Nrv4=Nref=512;
Option B: Nrv0=Nref=512; Nrv1=Nref/2=256; Nrv3=Nref=512; Nrv4=Nref/2=256; (or Nrv0=2×Nref=1024; Nrv1=Nref=512; Nrv3=2×Nref=1024; Nrv4=Nref=512)
Option C: Nrv0=Nref=512, Nrv1=Nref=512; Nrv3=2×Nref=1024; Nrv4=4×Nref=2048;
Option D: Nrv0=Nref=512, Nrv1=Nref=512; Nrv3=3×Nref=1536; Nrv4=3×Nref=1536.

Note that the mother code lengths for each transmission of all the above options in the first example and the second example can be extended (meaning the current four transmissions are a subset of more than four transmissions), or reduced (meaning the current four transmissions are a superset of less than four transmissions).

Some embodiments of the present disclosure may enable advantageous effects such as:

Flexibility in determining the mother code lengths of a polar code, and support for multiple mother code lengths.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

Features disclosed herein in the context of any particular embodiments may also or instead be implemented in other embodiments. Method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Although aspects of the present disclosure have been described with reference to specific features and embodiments thereof, various modifications and combinations can be made thereto without departing from the disclosure. The description and drawings are, accordingly, to be regarded simply as an illustration of some embodiments of the disclosure as defined by the appended claims, and are contemplated to cover any and all modifications, variations, combinations or equivalents that fall within the scope of the present disclosure. Therefore, although embodiments and potential advantages have been described in detail, various changes, substitutions and alterations can be made herein without departing from the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

Moreover, any module, component, or device exemplified herein that executes instructions may include or otherwise have access to a non-transitory computer readable or processor readable storage medium or media for storage of information, such as computer readable or processor readable instructions, data structures, program modules, and/or other data. A non-exhaustive list of examples of non-transitory computer readable or processor readable storage media includes magnetic cassettes, magnetic tape, magnetic disk storage or other magnetic storage devices, optical disks such as compact disc read-only memory (CD-ROM), digital video discs or digital versatile disc (DVDs), Blu-ray Disc™, or other optical storage, volatile and non-volatile, removable and non-removable media implemented in any method or technology, random-access memory (RAM), read-only memory (ROM), electrically erasable programmable read-only memory (EEPROM), flash memory or other memory technology. Any such non-transitory computer readable or processor readable storage media may be part of a device or accessible or connectable thereto. Any application or module herein described may be implemented using instructions that are readable and executable by a computer or processor may be stored or otherwise held by such non-transitory computer readable or processor readable storage media.

Simple standard description and low complexity.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

Features disclosed herein in the context of any particular embodiments may also or instead be implemented in other embodiments. Method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Acronyms, Abbreviations, and Initialisms

| | Acronym/ |
|---|---|
| | Abbreviation/ |
| Full Name | Initialism |
| Long Term Evolution | LTE |
| New Radio | NR |
| Forward error correction | FEC |
| Multiple Access | MA |
| Quality of Service | QoS |
| low-density parity check codes | LDPC |
| cyclic redundancy check | CRC |
| Parity check | PC |
| ultra-reliable low latency | uRLLC |
| communications | |
| Enhanced mobile broadband | eMBB |
| massive Machine Type Communications | mMTC |
| non-terrestrial networks | NTN |
| Internet of Things | IoT |
| Bit Error Rate | BER |
| Block Error Rate | BLER |
| Packet Error Rate | PER |
| Spectral Efficiency | SE |
| Hybrid automatic repeat request | HARQ |
| Incremental-redundancy HARQ | IR-HARQ |
| Channel Quality Indicator | CQI |
| Modulation Coding Scheme | MCS |
| gNodeB or 5G base station | gNB |
| user equipment | UE |
| Radio Resource Control | RRC |
| Radio Network Temporary Identifier | RNTI |
| Uplink Control Information | UCI |
| Downlink Control Information | DCI |
| Physical Broadcast Channel | PBCH |
| Half-radio frame bit | HRF |
| Synchronization Signal Block | SSB |
| unequal error protection | UEP |
| variable node | VN |

What is claimed is:

1. A method comprising:
determining a plurality of mother code lengths; and
encoding a plurality of information bits based on the plurality of mother code lengths to obtain a plurality of code words, wherein the plurality of code words correspond to the plurality of mother code lengths.

2. The method of claim 1, wherein determining a plurality of mother code lengths comprises:
determining the plurality of mother code lengths based on a set of parameters, wherein the set of parameters comprises one or more of the following:
a minimum code rate, a maximum code rate, a minimum mother code length, a maximum mother code length, a rate matching output length, an index of redundancy version, a transmission index, a number of transmission times, or a self-decodable indicator.

3. The method of claim 2, wherein each of the plurality of mother code lengths is related to a mother code length parameter and a first coefficient.

4. The method of claim 3, wherein the mother code length parameter is obtained by:
obtaining a rate matching output length, a number of the plurality of information bits, a minimum code rate, and a minimum mother code length;
obtaining a first stage mother code length based on the rate matching output length;
obtaining a second stage mother code length based on the number of the plurality of information bits and the minimum code rate;
obtaining a third stage mother code length; and
obtaining the mother code length parameter based on the first stage mother code length, the second stage mother code length, the third stage mother code length, and the minimum mother code length.

5. The method of claim 4, wherein the first stage mother code length is the smallest power-of-2 integer which is larger than the rate matching output length.

6. A method comprising:
obtaining a plurality of code words, wherein the plurality of code words correspond to a plurality of mother code lengths; and
decoding the plurality of code words to obtain a plurality of sequences, wherein the plurality of sequences correspond to a plurality of information bits.

7. The method of claim 6, wherein the plurality of mother code lengths are determined based on a set of parameters, the set of parameters comprising one or more of the following:
a minimum code rate, a maximum code rate, a minimum mother code length, a maximum mother code length, a rate matching output length, an index of redundancy version, a transmission index, a number of transmission times, or a self-decodable indicator.

8. The method of claim 7, wherein each of the plurality of mother code lengths is related to a mother code length parameter and a first coefficient.

9. The method of claim 8, wherein the mother code length parameter is obtained by:
obtaining a rate matching output length, a number of the plurality of information bits, a minimum code rate, and a minimum mother code length;
obtaining a first stage mother code length based on the rate matching output length;
obtaining a second stage mother code length based on the number of the plurality of information bits and the minimum code rate;
obtaining a third stage mother code length; and
obtaining the mother code length parameter based on the first stage mother code length, the second stage mother code length, the third stage mother code length, and the minimum mother code length.

10. The method of claim 9, wherein the first stage mother code length is the smallest power-of-2 integer which is larger than the rate matching output length.

11. An apparatus, comprising:
at least one processor coupled with at least one memory storing one or more instructions that, when executed by the at least one processor, cause the apparatus to perform operations comprising:
determining a plurality of mother code lengths; and
encoding a plurality of information bits based on the plurality of mother code lengths to obtain a plurality of code words, wherein the plurality of code words correspond to the plurality of mother code lengths.

12. The apparatus of claim 11, wherein the determining a plurality of mother code lengths comprises determining the plurality of mother code lengths based on a set of parameters, the set of parameters comprising one or more of the following:
a minimum code rate, a maximum code rate, a minimum mother code length, a maximum mother code length, a rate matching output length, an index of redundancy version, a transmission index, a number of transmission times, or a self-decodable indicator.

13. The apparatus of claim 12, wherein each of the plurality of mother code lengths is related to a mother code length parameter and a first coefficient.

14. The apparatus of claim 13, wherein the mother code length parameter is obtained by:
obtaining a rate matching output length, a number of the plurality of information bits, a minimum code rate, and a minimum mother code length;
obtaining a first stage mother code length based on the rate matching output length;
obtaining a second stage mother code length based on the number of the plurality of information bits and the minimum code rate;
obtaining a third stage mother code length; and
obtaining the mother code length parameter based on the first stage mother code length, the second stage mother code length, the third stage mother code length, and the minimum mother code length.

15. The apparatus of claim 14, wherein the first stage mother code length is the smallest power-of-2 integer which is larger than the rate matching output length.

16. An apparatus, comprising:
at least one processor coupled with at least one memory storing one or more instructions that, when executed by the at least one processor, cause the apparatus to perform operations comprising:
obtaining a plurality of code words, wherein the plurality of code words correspond to a plurality of mother code lengths; and
decoding the plurality of code words to obtain a plurality of sequences, wherein the plurality of sequences correspond to a plurality of information bits.

17. The apparatus of claim 16, wherein the plurality of mother code lengths are determined based on a set of parameters, the set of parameters comprising one or more of the following:
a minimum code rate, a maximum code rate, a minimum mother code length, a maximum mother code length, a rate matching output length, an index of redundancy version, a transmission index, a number of transmission times, or a self-decodable indicator.

18. The apparatus of claim 17, wherein each of the plurality of mother code lengths is related to a mother code length parameter and a first coefficient.

19. The apparatus of claim 18, wherein the mother code length parameter is obtained by:
obtaining a rate matching output length, a number of the plurality of information bits, a minimum code rate, and a minimum mother code length;
obtaining a first stage mother code length based on the rate matching output length;
obtaining a second stage mother code length based on the number of the plurality of information bits and the minimum code rate;
obtaining a third stage mother code length; and
obtaining the mother code length parameter based on the first stage mother code length, the second stage mother code length, the third stage mother code length, and the minimum mother code length.

20. The apparatus of claim 19, wherein the first stage mother code length is the smallest power-of-2 integer which is larger than the rate matching output length.
